(19) United States
(12) Patent Application Publication
(10) Pub. No.: US 2012/0067414 A1
(43) Pub. Date: Mar. 22, 2012

(54) CdZnO OR SnZnO BUFFER LAYER FOR SOLAR CELL

(76) Inventors: Chungho Lee, San Jose, CA (US); Zhibo Zhao, Novi, MI (US); Benyamin Buller, Perrysburg, OH (US); Rui Shao, Sylvania, OH (US)

(21) Appl. No.: 13/240,082

(22) Filed: Sep. 22, 2011

Related U.S. Application Data
(60) Provisional application No. 61/385,398, filed on Sep. 22, 2010.

(51) Int. Cl. H01L 31/02; B32B 5/00; B32B 17/06; H01L 31/0216; H01L 31/18; H01L 31/0264; H01L 31/0272; H01L 31/0296; H01L 31/0376; B32B 9/00; H01L 31/0224

(52) U.S. Cl. 136/256; 428/697; 428/336; 428/426; 136/252; 136/260; 136/262; 136/258; 438/85; 257/E31.015

(57) ABSTRACT

A structure for use in a photovoltaic device is disclosed, the structure includes a substrate, a buffer material, a barrier material in contact with the substrate; and a transparent conductive oxide between the buffer material and the barrier material. The buffer material comprises at least one of CdZnO and SnZnO. The structure can be included in a photovoltaic device. Methods for forming the structure are also disclosed.

### CLAIM FOR PRIORITY

This application claims priority under 35 U.S.C. §119(e) to Provisional U.S. Patent Application Ser. No. 61/385,398, filed on Sep. 22, 2010, which is hereby incorporated by reference.

### FIELD OF THE INVENTION

This invention pertains to photovoltaic structures, devices, and methods of forming the same.

### BACKGROUND OF THE INVENTION

Photovoltaic devices, such as solar cells, can include a semiconductor, which absorbs light and converts it into electron-hole pairs. A semiconductor junction (e.g., a p-n junction), separates the photo-generated carriers (electrons and holes). A contact allows the current to flow to the external circuit. More recently, photovoltaic devices have used conductive transparent thin films to generate charge from incident light. There is a continuing need to improve performance for such thin film photovoltaic devices.

### BRIEF DESCRIPTION OF THE DRAWINGS

FIG. 1 depicts a substrate structure according to an embodiment.

FIG. 2 depicts a device according to an embodiment.

FIGS. 3 and 3B depict the formation of the substrate structure of FIG. 1.

FIG. 4A Depicts a solar module including the device of FIG. 2.

FIG. 4B Depicts a solar array including the module of FIG. 4A.

### DETAILED DESCRIPTION OF THE INVENTION

In the following detailed description, reference is made to the accompanying drawings which form a part hereof, and in which are shown by way of illustration specific embodiments that may be practiced. It should be understood that like reference numbers represent like elements throughout the drawings. These example embodiments are described in sufficient detail to enable those skilled in the art to practice them. It is to be understood that other embodiments may be utilized, and that structural, material, and electrical changes may be made, only some of which are discussed in detail below.

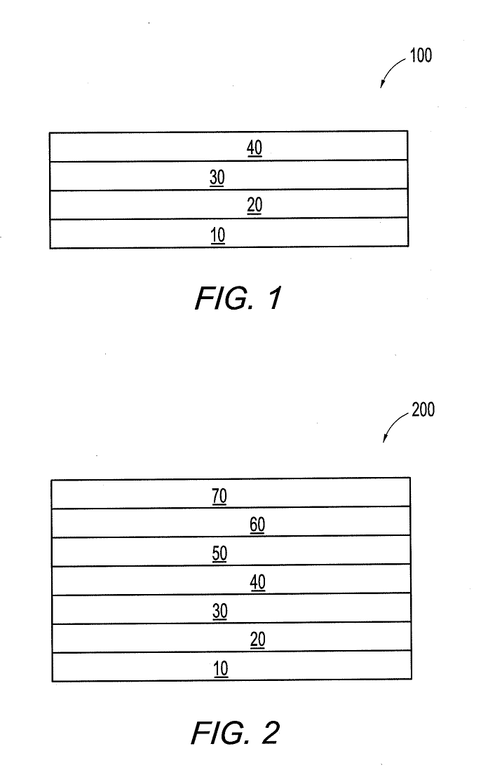

A configuration for a substrate structure used for thin-film photovoltaic devices consists of multiple layers deposited over a glass material. An exemplary substrate structure 100 is shown in FIG. 1, which includes a substrate 10, one or more barrier materials 20, one or more transparent conductive oxides (TCO) 30, and one or more buffer materials 40. The TCO material 30 (alone or in combination with other materials, layers or films) can serve as a first contact. Each of these materials (10, 20, 30, 40) can include one or more layers or films, one or more different types of materials and/or or same material types with differing compositions.

The substrate 10 can be, for example, glass, such as soda lime glass, low Fe glass, solar float glass or other suitable glass. The barrier material 20 can be silicon oxide, silicon aluminum oxide, tin oxide, or other suitable material or a combination thereof The TCO material 30 can be fluorine doped tin oxide, cadmium tin oxide, cadmium indium oxide, aluminum doped zinc oxide or other transparent conductive oxide or combination thereof The buffer material 40 is described in more detail below.

The substrate structure 100 can be included in a device 200, e.g., a photovoltaic device such as a solar cell, as shown in FIG. 2. In addition, the device 200 includes a window material 50, a semiconductor material 60 and a second contact 70. Each if these materials (50, 60, 70) can include one or more layers or films, one or more different types of materials and/or or same material types with differing compositions.

The window material 50 may be a semiconductor material, such as CdS, ZnS, CdZnS, ZnMgO, Zn (O,S) or other suitable photovoltaic semiconductor material. The semiconductor material 60 can be CdTe, CIGS, amorphous silicon, or any other suitable photovoltaic semiconductor material. The second contact 70 can be a metal or other highly conductive material, such as molybdenum, aluminum or copper.

Although the materials 10, 20, 30, 40, 50, 60, 70 are shown stacked with the substrate 10 on the bottom, the materials 10, 20, 30, 40, 50, 60, 70 can be reversed such that the second contact 70 is on the bottom or arranged in a horizontal orientation. Optionally, additional materials, layers and/or films may be included in the substrate structure 100 or device 200, such as AR coatings, color suppression layers, among others.

The buffer material 40, which directly contacts the semiconductor materials 60, is important for the performance and stability of the device 200. For example, in a device 200 that uses CdTe (or similar material) as the semiconductor material 60, the buffer material 40 is a relatively resistive material as compared to the TCO material 30, and provides an interface for the window material 50 and TCO material 30. Among the solar cell performance parameters, open circuit voltage (Voc) and short-circuit conductance (Gsc) are closely related to the buffer material 40 design.

According to one embodiment, the buffer material 40 comprises a single layer of GZnO, where G is Cd or Sn. In another embodiment, the buffer material 40 comprises a layer of GZnO and a layer of any other transparent conductive material. In another embodiment the buffer material 40 includes a layer of GZnO and a layer of SnOₓ. The buffer material 40 may have a thickness from about 0.1 nm to about 1000 nm, or from about 0.1 nm to about 300 nm.

In one embodiment, a device 200 includes a glass 10, a barrier material 20 of SiAlOₓ (about 2000 Å), a TCO material 30 of CdSt (about 2000 Å), a buffer material 40 of GZnO (about 750 Å), a window material 50 of CdS (about 750 Å), a semiconductor material 60 of CdTe (about 3 μm), and a second contact of a highly conductive material (e.g., molybdenum, aluminum, or copper).

In another embodiment, a device 200 includes a glass 10, barrier material 20 comprising a layer of SnOₓ and a layer of SiAlOₓ (totaling about 500 Å), a TCO material 30 of SnO₂:F (about 4000 Å), a buffer material 40 of GZnO (about 750 Å), a window material 50 of CdS (about 750 Å), an semiconductor material 60 of CdTe (about 3 μm), and a second contact of a highly conductive material (e.g., molybdenum, aluminum, copper).

In each embodiment described above, the ratio of G to Zn can be from about 1:100 to about 100:1.

GZnO material or the entire buffer material 40 may be doped. Dopants can be used to achieve a desired conductivity of the buffer material 40 as compared to the TCO material 30. In one embodiment, the buffer material 40 is less conductive than the TCO material 30. Dopants can be n-type or p-type elements. For example, group I elements (e.g., Li, Na, and K) and group V elements (e.g., N, P, As, Sb, and Bi) are p type candidates, and group III elements (e.g., B, Al, Ga and In) and group VII elements (e.g., F, Cl, Br, I, and At) are n-type candidates. In one embodiment, the effective concentration of dopant in the buffer material 40 (or in the GZnO material) is between about 1×10¹⁴ atoms/cm³ to about 1×10²⁰ atoms/cm³.

The buffer material 40 provides an interface between the TCO material 30 (highly conductive) and the window material 50 (relatively resistive). To optimize the interface, there should be a good energy band alignment between TCO material 30 and the window material 50. This can be achieved by adjusting the buffer material 40 doping. For example, if a CdS window material 50 is thin it can become non-conformal and some buffer material 40 will directly contact the semiconductor material 60 (e.g., CdTe), which will change the band alignment. Therefore, depending on the thickness or doping level of the CdS window material 50, the buffer material 40 doping is selected to provide a good energy band alignment between TCO material 30 and the window material 50.

Alternatively, a desired conductivity for the buffer material 40 can be achieved by controlling oxygen deficiencies of sub-oxides. For example, the amount of oxygen deficiency can be altered by changing oxygen/argon ratios during a reactive sputtering process as described in more detail below.

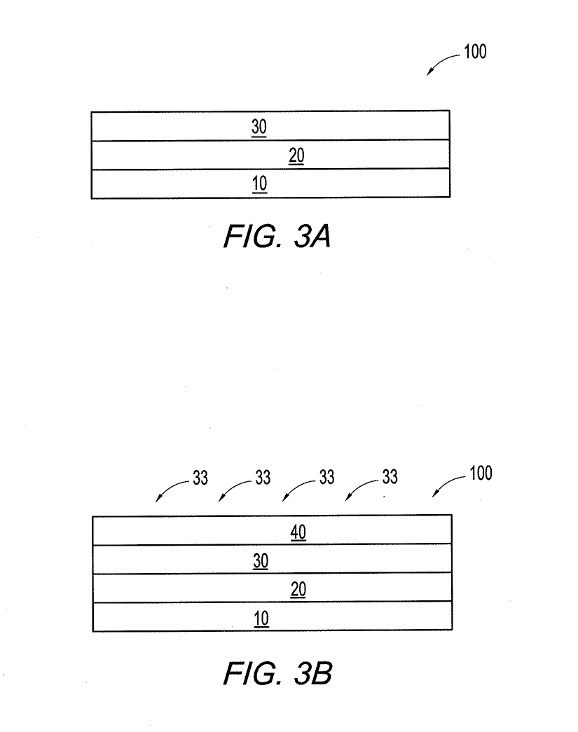

FIGS. 3A and 3B depict the formation of the FIG. 1 substrate structure 100. As shown in FIG. 3A, a substrate 10 is provided. The barrier material 20 and TCO material 30 are formed over the substrate 10. Each of these materials 20, 30 can be formed by known processes. For example, the barrier material 20 and the TCO material 30 can be formed by physical vapor deposition processes, chemical vapor deposition processes or other suitable processes.

As shown in FIG. 3B, the buffer material 40 is formed over the TCO material 30. The buffer material 40 can be deposited by physical, chemical deposition, or any other deposition methods (e.g., atmospheric pressure chemical vapor deposition, evaporation deposition, sputtering and MOCVD, DC Pulsed sputtering, RF sputtering or AC sputtering). If a sputtering process is used, the target can be a ceramic target or a metallic target. Further, the sputtering may be conducted using a pre-alloyed target or by co-sputtering from G and Zn targets.

Arrows 33 depict the optional step of doping the buffer material 40, which can be accomplished in any suitable manner.

In one embodiment, the dopant is introduced into the sputtering target(s) at desired concentrations. A sputtering target can be prepared by casting, sintering or various thermal spray methods. In one embodiment, the buffer material 40 is formed from a pre-alloy target comprising the dopant by a reactive sputtering process. In one embodiment, the dopant concentration of the sputter target is about 1×10¹⁷ atoms/cm³ to about 1×10¹⁸ atoms/cm³. In one embodiment, the buffer material 40 is formed by a sputtering process using a target of Cd—Zn or Sn—Zn and a target comprising the dopant, and such targets may be placed adjacent one another during the sputtering process.

In addition, conductivity of the buffer material 40 can be changed by controlling thermal processing of the buffer material 40. The buffer material 40 is an amorphous material upon deposition. By thermal processing, e.g., thermal annealing, the buffer material 40 can be converted (in whole or in part) to a crystalline state, which is more conductive relative to the amorphous state. In addition, the active dopant level (and thereby the conductivity) can be varied by thermal processing, e.g., thermal annealing. In this case, both thermal load (i.e., the time of exposure to a temperature and the temperature) and ambient conditions can be manipulated to affect doping levels in the buffer material 40. For example, a slightly reducing or oxygen-depleting environment during an annealing process can lead to higher doping levels and thus enhanced conductivity accordingly. Furthermore, a thermal treating process can be a separate annealing process after deposition of the buffer material 40 (and before the formation of any other materials on the buffer material 40) or the processing used in the depositions of the window material 50 and/or the semiconductor material 60. The thermal processing can be done at temperatures from about 300° C. to about 800° C.

Alternatively, a desired conductivity for the buffer material 40 can be achieved by controlling oxygen deficiencies of sub-oxides. For example, the amount of oxygen deficiencies can be altered during the formation of the buffer material 40 by introducing gases and changing the ratio of oxygen to other gasses, e.g., oxygen/argon ratio, during a reactive sputtering process. Generally, for a metal oxide, if it is oxygen deficient, extra electrons of the metal can participate in the conductance, increasing the conductivity of the material. Thus, conductivity of the buffer material 40 can be increased by controlling the deposition chamber gas to be oxygen deficient (i.e., by forming the buffer material 40 in an oxygen deficient environment). For example, supplying forming gas will reduce the available oxygen gas.

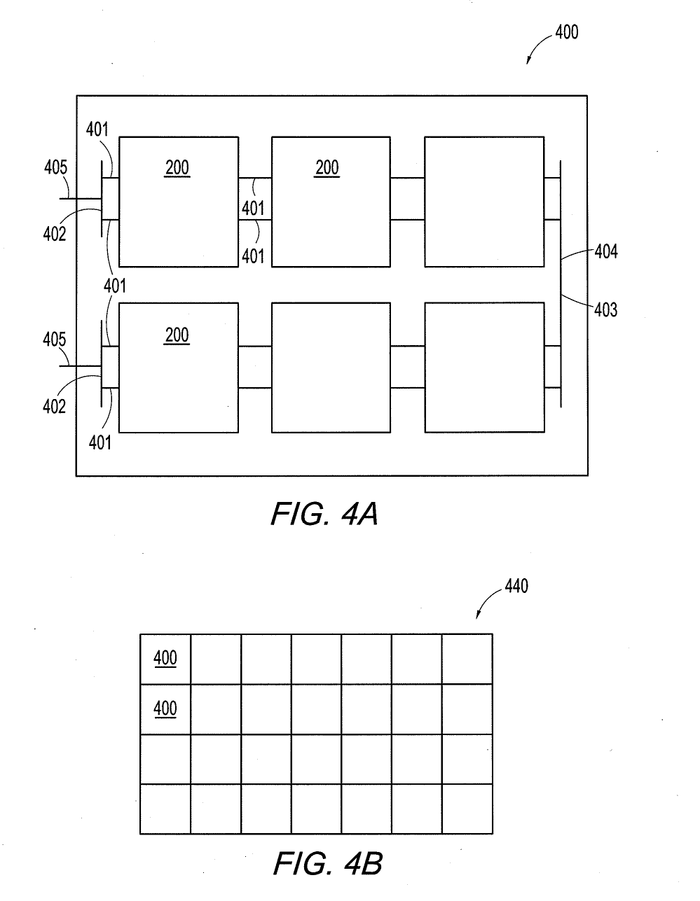

FIG. 4A depicts a solar module 400, including devices 200, which can be solar cells. Each of the solar cells 200 is electrically connected via leads 401 to buses 402, 403. The buses 402, 403 can be electrically connected to leads 404, 405, which can be used to electrically connect a plurality of modules 400 to form an array 440, as shown in FIG. 4B.

While disclosed embodiments have been described in detail, it should be readily understood that the invention is not limited to the disclosed embodiments. Rather the disclosed embodiments can be modified to incorporate any number of variations, alterations, substitutions or equivalent arrangements not heretofore described.

What is claimed as new and desired to be protected by Letters Patent of the United States is:

1. A structure for use in a photovoltaic device, the structure comprising:
a substrate;
a buffer material, wherein the buffer material comprises at least one of CdZnO and SnZnO.
a barrier material in contact with the substrate; and
a transparent conductive oxide between the buffer material and the barrier material.

2. The structure of claim 1, wherein buffer material further comprises a dopant.

3. The structure of claim 2, wherein the dopant comprises a p-type dopant.

4. The structure of claim 3, wherein the dopant is selected from the group consisting of: Li, Na, K, N, P, As, Sb, and Bi.

5. The structure of claim 2, wherein the dopant comprises an n-type dopant.

6. The structure of claim 5, wherein the dopant is selected from the group consisting of: B, Al, Ga, In, T, F, Cl, Br, I, and At.

7. The structure of claim 2, wherein the concentration of the dopant is from about 1×10¹⁴ atoms/cm³ to about 1×10²⁰ atoms/cm³.

8. The structure of claim 1, wherein the buffer material has a thickness from about 0.1 nm to about 1000 nm.

9. The structure of claim 1, wherein the buffer material has a thickness from about 0.1 nm to about 300 nm.

10. The structure of claim 1, wherein the buffer material further comprises at least one other transparent material.

11. The structure of claim 1, wherein the buffer material further comprises SnOₓ.

12. The structure of claim 1, wherein the buffer material comprises CdZnO and wherein the atomic ratio of Cd to Zn is from about 1:100 to about 100:1.

13. The structure of claim 1, wherein the buffer material comprises SnZnO and wherein the atomic ratio of Sn to Zn is from about 1:100 to about 100:1.

14. The structure of claim 1, wherein the substrate is a glass selected from the group consisting of: soda lime glass, low Fe glass and solar float glass.

15. A photovoltaic device comprising:
a substrate;
a semiconductor material;
a barrier material between the substrate and the semiconductor material;
a transparent conductive oxide between the barrier material and the semiconductor material;
a buffer material between the transparent conductive oxide and the semiconductor material, wherein the buffer material comprises at least one of CdZnO and SnZnO; and
a window material between the buffer material and the semiconductor material.

16. The device of claim 15, wherein buffer material further comprises a dopant.

17. The device of claim 16, wherein the concentration of the dopant is from about 1×10¹⁴ atoms/cm³ to about 1×10²⁰ atoms/cm³.

18. The device of claim 15, wherein the buffer material has a thickness from about 0.1 nm to about 1000 nm.

19. The device of claim 15, wherein the buffer material further comprises at least one other transparent material.

20. The device of claim 15, wherein the buffer material comprises CdZnO and wherein the atomic ratio of Cd to Zn is from about 1:100 to about 100:1.

21. The device of claim 15, wherein the buffer material comprises SnZnO and wherein the atomic ratio of Sn to Zn is from about 1:100 to about 100:1.

22. The device of claim 1, further comprising a contact adjacent the semiconductor material.

23. The device of claim 15, wherein the semiconductor material is selected from the group consisting of: CdTe, CIGS and amorphous silicon.

24. The device of claim 15, wherein the substrate comprises a glass, the barrier material comprises SiAlOₓ, the TCO material comprises CdSt, the window material comprises CdS, and the semiconductor material comprises CdTe.

25. The device of claim 15, wherein the substrate comprises a glass, the barrier material comprises SnOₓand SiAlOₓ, the TCO material comprises flouring doped SnO₂, the window material comprises CdS, and the semiconductor material comprises CdTe.

26. The device of claim 15, wherein a portion of the buffer material is in direct contact with a portion of the semiconductor material.

27. A method of making a photovoltaic structure, the method comprising:
providing a substrate;
forming a barrier material on a first side of the substrate;
forming a transparent conductive oxide on the first side of the substrate; and
forming a buffer material on the first side of the substrate, wherein the buffer material comprises at least one of CdZnO and SnZnO; and wherein the barrier material is between the transparent conductive oxide and the substrate; and the transparent conductive oxide is between the buffer material and the barrier material.

28. The method of claim 27, further comprising doping the barrier material with a dopant.

29. The method of claim 28, wherein the buffer material is formed by a sputtering process, and wherein doping the buffer material comprises using a target having the dopant in a concentration from about 1×10¹⁷ atoms/cm³ to about 1×10¹⁸ atoms/cm³.

30. The method of claim 27, wherein at least one of the barrier material, transparent conductive oxide and buffer material are formed by atmospheric physical vapor deposition.

31. The method of claim 27, further comprising subjecting the barrier material to a thermal annealing process.

32. The method of claim 27, wherein forming the buffer material comprises forming the buffer material in an oxygen deficient environment.

33. The method of claim 27, wherein the buffer material is formed in an amorphous state and further comprising processing the buffer material to change at least a portion of the buffer material to a crystalline state.
